(19) United States
(12) Patent Application Publication
(10) Pub. No.: US 2003/0218500 A1
(43) Pub. Date: Nov. 27, 2003

(54) Power amplifier capable of switching gain while suppressing noise power in reception band

(75) Inventors: Kazuya Yamamoto, Hyogo (JP); Teruyuki Shimura, Hyogo (JP); Tomoyuki Asada, Hyogo (JP); Satoshi Suzuki, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/298,610

(22) Filed: Nov. 19, 2002

(30) Foreign Application Priority Data
May 22, 2002 (JP) 2002-148071(P)

(51) Int. Cl. H03F 1/14; H03F 3/68

(52) U.S. Cl. 330/51; 330/126

(57) ABSTRACT

An amplification part of a power amplifier includes first to third amplifier stages and a signal transmission part provided in parallel with the first amplifier stage. When a mode select voltage Vmod2 is set to the L level, an input signal is amplified by the first to third amplifier stages. At this time, the signal transmission part does not transmit signals. On the other hand, when mode select voltage Vmod2 is set to the H level, the signal transmission part transmits the input signal to a transistor via a diode. At this time, a control voltage Vmod1800 is set to the L level, and the first amplifier stage is turned off, so that power consumption is reduced. Thus, a power amplifier capable of switching a gain in accordance with GSM/EDGE modes while suppressing noise power in a reception band can be provided.

### BACKGROUND OF THE INVENTION

1. Field of the Invention

The present invention relates to a bipolar transistor power amplifier typified by a GaAs hetero-junction bipolar transistor (hereinafter, referred to as HBT) and an SiGe-HBT, and more particularly to a power amplifier capable of switching its linear gain.

2. Description of the Background Art

At present, as power amplifiers for mobile communications, an MMIC (Monolithic Microwave IC) or a module (hybrid IC, MMIC module or multi-chip module) using a GaAs MESFET Metal Semiconductor Field-Effect Transistor), a GaAs HEMT (High Electron Mobility Transistor), and GaAs HBT is widely used.

Among the transistors, a GaAs-HBT using a hetero-junction of gallium arsenide (GaAs) and an SiGe-HBT using a hetero-junction of silicon germanium (SiGe) have the following advantages in comparison with a conventional FET (Field Effect Transistor), so that they are most expected as present power devices for mobile communications:

(1) a single power supply operation can be realized without requiring a negative gate bias voltage;

(2) an output on/off operation can be performed without provided an analog switch on the drain (collector) side in a manner similar to an Si-MOSFET (Insulated-Gate Field-Effect Transistor); and

(3) A high power density and a specified output can be obtained by using a power amplifier smaller than an FET power amplifier.

A typical application of mobile communications is a portable telephone system. The portable telephone systems include European GSM (Global System for Mobile Communications) as a portable telephone system using a 900 MHz band which is most widely used at present and DCS (Digital Cordless Systems) as portable telephone systems using the 1800 MHz band which are widely used in Europe. In the communication systems such as GSM and DCS, a portable telephone of high output from 1 W to 4 W is used and, as a power amplifier for the portable telephone, in place of an Si-MOSFET power amplifier which is in the mainstream, a power amplifier utilizing the characteristics of an HBT (HBT power amplifier) is now being applied.

In future, service of an EDGE (Enhanced Data rate for GSM Evolution) system capable of obtaining data transfer speed higher than that of the GSM system is going to be provided. For start of the service, realization of a power amplifier adapted to dual band/dual mode including a GSM/EDGE switching function and a power amplifier adapted to triple band/dual mode is strongly demanded. The dual band can switch between the 900 MHz band and the 1800 MHz band. The triple band can switch between the 900 MHz band and the 1800/1900 MHz band. The 1900 MHz band is a band used in the PCS (Personal Cellular Systems) in U.S.A. The dual mode is a mode capable of making a switch between the GSM system and the EDGE system.

FIG. 12 is a diagram showing a part of the configuration of a circuit of a conventional HBT power amplifier for the GSM/DCS dual band.

A power amplifier for dual band constructed by two circuits of FIG. 12 and a band select switch is disclosed by Yamamoto et al., “A 3.2-V Operation Single-Chip Dual-Band AlGaAs/GaAs HBT MMIC Power Amplifier With Active Feedback Circuit Technique”, FIG. 1, IEEE JOURNAL OF SOLID STATE CIRCUITS, VOL., 35, NO. 8, AUGUST, 2000.

Referring to FIG. 12, on a semiconductor chip 528 of a GaAs substrate, a bias circuit 540 and a power amplifying circuit 520 are provided.

Power amplifying circuit 520 includes an input matching circuit 521 to which an input signal IN is supplied from an input terminal via a line 504, a first amplifier stage 522 for receiving and amplifying an output of input matching circuit 521, a second amplifier stage 523, a third amplifier stage 525, a capacitor C1 for matching amplifier stages 522 and 523, and an interstage matching circuit 524 for matching amplifier stages 523 and 525.

Input matching circuit 521 includes resistors Ra1, Ra2 and Ra3 constructing an attenuator for receiving input signal IN supplied via line 504, and a capacitor Cin1 connected between nodes N53 and N54.

Amplifier stage 522 includes a resistor Rb1 having an end to which a bias voltage Vb1 is applied and the other end connected to node N54, a resistor R1 having an end connected to node N54, and a transistor Tr1 having a base connected to the other end of resistor R1 and an emitter connected to a ground node. The collector of transistor Tr1 is connected to a terminal 562. A collector power supply potential Vc1 is applied to terminal 562 via a line L1. A capacitor Cdc1 is provided between a terminal to which collector power supply potential Vc1 is applied and the ground node.

Capacitor C1 for matching amplifier stages 522 and 523 is connected between the collector of transistor Tr1 and a node N55.

Amplifier stage 523 includes a resistor Rb2 having an end to which a bias voltage Vb2 is applied and the other end connected to node N55, a resistor R2 having an end connected to node N55, a transistor Tr2 having a base connected to the other end of resistor R2 and an emitter connected to the ground node, a capacitor Cf2 connected between the collector of transistor Tr2 and a node N57, and a resistor Rf2 connected between nodes N57 and N55. An output of transistor Tr2 is fed back to node N55 via capacitor Cf2 and resistor Rf2. The collector of transistor Tr2 is connected to a terminal 564. A collector power supply potential Vc2 is applied to terminal 564 via a line L2. A capacitor Cdc2 is connected between the terminal to which collector power supply potential Vc2 is applied and the ground node.

Amplifier stage 525 includes a resistor Rb3 having an end to which a bias voltage Vb3 is applied and the other end connected to a node N56, a resistor R3 having an end connected to node N56, a transistor Tr3 having a base connected to the other end of resistor R3 and an emitter connected to the ground node, a capacitor Cf3 connected between the collector of transistor Tr3 and a node N58, and a resistor Rf3 connected between nodes N58 and N56. An output of transistor Tr3 is fed back to node N56 via capacitor Cf3 and resistor Rf3. The collector of transistor Tr3 is connected to a terminal 532.

A matching circuit 536 is connected to terminal 532. A collector power supply potential Vc3 is applied to matching circuit 536, and a signal OUT is output from an output terminal.

Bias circuit 540 includes bias voltage control circuits 541 to 543 outputting bias voltages Vb1 to Vb3, respectively.

Bias voltage control circuit 541 includes a resistor Rbb12 having an end to which a band select voltage Vmod is applied, a transistor TrB_1 having a base connected to the other end of resistor Rbb12 and an emitter connected to the ground node, a resistor Rcc1 connected between the collector of transistor TrB_1 and a node N59, and a resistor Rbb11 connected between node N59 and a node N63.

A control voltage Vpc is applied to node N63 via a line 508. A capacitor 506 is provided between the terminal to which control voltage Vpc is applied and the ground node. Bias voltage Vb1 is output from node N59.

Bias voltage control circuit 542 includes a resistor Rbb2 having an end connected to node N63, a transistor TrB_2 having a base connected to the other end of resistor Rbb2 and an emitter connected to a node N61, a resistor Ree2 connected between node N61 and the ground node, and a resistor Rcc2 connected between a node N64 and the collector of transistor TrB_2. A power supply potential Vcc is applied to node N64 via a line 556. A capacitor 552 is connected between the terminal which receives power supply potential Vcc and the ground node. Bias voltage Vb2 is outputted from node N61.

Bias voltage control circuit 543 includes a resistor Rbb3 having an end connected to node N63, a transistor TrB_3 having a base connected to the other end of resistor Rbb3 and an emitter connected to a node N62, a resistor Ree3 connected between node N62 and the ground node, and a resistor Rcc3 connected between a node N65 and the collector of transistor TrB_3. Power supply potential Vcc is applied to node N65 via a line 554. Bias voltage Vb3 is outputted from node N62.

As transistors Tr1 to Tr3, for example, GaAs HBTs for amplifying an RF (Radio Frequency) signal are used. Transistor TrB_1 is a switch transistor for setting transistor Tr1 of the first power amplifier stage to an off state when band select voltage Vmod is at the H level. Transistors TrB_2 and TrB_3 are made conductive when control voltage Vpc is at H Level and output bias voltages Vb2 and Vb3 from their emitters, respectively.

On a conventional power amplifier for dual band, a power amplifier for GSM, a power amplifier for DCS, and a band select switch are mounted. Each of the power amplifier for GSM and power amplifier for DCS has a configuration as shown in FIG. 12. One of the amplifiers is selectively operated by a not-illustrated band select switch.

When control voltage Vpc is set to the L level (for example, 0V), bias voltages Vb1 to Vb3 are made inactive, so that the circuit shown in FIG. 12 is turned off.

For example, when band select voltage Vmod is set to the L level (for example, 0V), control voltage Vpc on the side of the power amplifier for GSM is set to an active state by the not-illustrated band select switch to make the operation of the power amplifier for GSM active. At this time, control voltage Vpc of the power amplifier for DCS is set to an inactive state of the L level by the band select switch to make the operation of the power amplifier for DCS inactive.

On the contrary, when band select voltage Vmod is set to the H level (for example, 2.8V), control voltage Vpc of the power amplifier for GSM is set to the inactive state of the L level by the band select switch to make the operation of the power amplifier for GSM inactive. By setting control voltage Vpc of the power amplifier for DCS active, the operation of the power amplifier for DCS is made active.

A case of realizing a dual mode used for both the GSM and EDGE systems by the power amplifier as shown in FIG. 12 will be considered.

In the GSM mode, constant envelope modulation is performed. In the constant envelope modulation, a saturating power amplifier of a large output realizing high efficiency operation is used. Consequently, usually, the gain of a power amplifier having a linear gain of at least 40 dB is decreased, and the power amplifier is used in a state where the power gain is about 30 dB. In such a manner, high-output operation of about 35 dBm and high-efficiency operation of 50% or higher are performed.

On the other hand, as the EDGE mode, PSK (Phase Shift Keying) modulation is employed. Since the PSK modulation needs high linearity, an amplifier of which gain reduction is large cannot be applied for the reason that it causes amplitude and phase distortions. An amplifier realizing desired power of about 30 dBm and an operation at an efficiency of about 20% to 30% by an operation of reducing the gain by 1 dB to 2 dB is used.

The problem in this case is noise power in a reception band.

FIG. 13 is a diagram schematically showing the relation between reception band noise and main signals.

Referring to FIG. 13, the problem in transmission in the GSM mode is noise power occurring in a reception band (935 MHz band) higher than the highest channel (915 MHz band) in the GSM transmission band by 20 MHz when the GSM transmission band is used. The noise level has to be suppressed to about −80 dBm or less in the radio standard. However, as will be described below, it is difficult for the power amplifier having a high linear gain to realize the radio standard.

Generally, noise power in a reception band is expressed by the following equation.

$$\begin{matrix}N [ dBm \text{/} 100 kHz ] = - 174 dBm \text{/} Hz \cdot 100 kHz + F [ dB ] + G [ dB ] \\ = - 124 dBm + F [ dB ] + G [ dB ]\end{matrix} \qquad ( 1 )$$

where N denotes reception noise power per 100 kHz, −174 dBm/Hz indicates natural noise, F indicates an NF (noise factor or noise figure) in the reception band of the power amplifier, which is usually 6 to 10 dB, and G represents the gain of the power amplifier in the reception band.

In the equation (1), in the case of suppressing N to −80 dBm or lower, the total of noise factor F, and gain G has to be suppressed to 44 dB or lower. That is, when it is assumed that noise figure F is 6 to 10 dB, gain G has to be as low as 34 to 38 dB.

Therefore, the gain of the power amplifier has to be switched between the GSM mode and the EDGE mode. In this case, it is necessary not to largely deteriorate the noise factor of the amplifier.

An example of the conventional technique of gain switching relates to a circuit used in a wide-band amplifier for optical communications and the like.

FIG. 14 is a diagram showing a circuit example of a wideband amplifier.

Referring to FIG. 14, a diode 602 is connected between an input and an output of an amplifier 600. The anode of diode 602 is connected to the input of amplifier 600, and the cathode of diode 602 is connected to the output of amplifier 600.

When an excessive input signal arrives at the circuit of FIG. 14, the signal passes through diode 602. As a result, the gain of amplifier 600 drops. In the circuit, when the amplitude of the input signal is small, diode 602 is in the off state. When the amplitude of the input signal becomes large, diode 602 is automatically turned on. Since the gain changes according to the magnitude of the input signal, such a conventional configuration cannot be used in the case where the gain is switched between the GSM mode and the EDGE mode.

As described above, in the HBT power amplifier, the gain of the power amplifier has to be switched between the GSM mode and the EDGE mode. In this case, it is necessary not to largely deteriorate noise factor NF of the amplifier. However, in the case where an FET switch adapted to transfer/interrupt signals cannot be easily used like in a monolithic type HBT power amplifier as dealt in the present invention, particularly, a, compound semiconductor integrated circuit using an RF signal, a proper circuit for realizing switching of the gain has not been devised.

### SUMMARY OF THE INVENTION

An object of the present invention is to provide an HBT power amplifier capable of switching the gain, which is integrated on a single chip.

According to the present invention, in short, a power amplifier having first and second modes as operation modes, includes first and second amplifying elements, and a transmission circuit.

The first amplifying element amplifies an input signal in the first mode and is set in an inactive state in the second mode. The second amplifying element further amplifies an output of the first amplifying element in the first mode and amplifies the input signal in the second mode. The transmission circuit performs a first operation of blocking transmission of the input signal to the second amplifying element in the first mode and a second operation for transmitting the input signal to the second amplifying element in the second mode, and switching the first and second operations in accordance with a mode setting signal.

Therefore, a main advantage of the present invention is that the gain can be switched without increasing noise power in a reception band.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing the configuration of a power amplifier 1 of a first embodiment of the present invention;

FIG. 2 is a circuit diagram showing the configuration of an amplification part 28 in FIG. 1;

FIG. 3 is a diagram showing the characteristic of a diode D1 of a signal transmission part 58 in FIG. 2;

FIG. 4 is a diagram for describing a transistor as diode D1;

FIG. 5 is a circuit diagram showing the configuration of an amplification part 28A used in place of amplification part 28 in a power amplifier of a second embodiment;

FIG. 6 is a circuit diagram showing the configuration of an amplification part 28B used in place of amplification part 28 shown in FIG. 2, in a third embodiment;

FIG. 7 is a circuit diagram showing the configuration of an amplification part 28C used in a power amplifier of a fourth embodiment;

FIG. 8 is a circuit diagram showing the configuration of an amplification part 28D used in a fifth embodiment;

FIG. 9 is a circuit diagram showing the configuration of an amplification part 28E used in a sixth embodiment;

FIG. 10 is a circuit diagram showing the configuration of an amplification part 28F used in a seventh embodiment;

FIG. 11 is a circuit diagram showing the configuration of a switch circuit 100G;

FIG. 12 is a diagram showing a part of the circuit configuration of a conventional HBT power amplifier for GSM/DCS dual band;

FIG. 13 is a diagram schematically showing the relation between reception band noise and a main signal; and

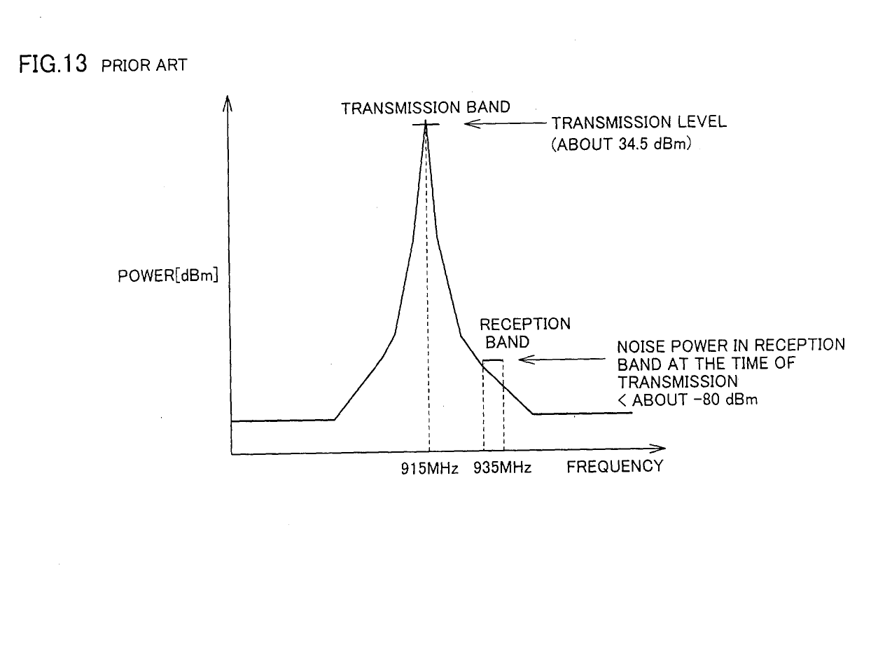

FIG. 14 is a diagram showing a circuit example of a wideband amplifier.

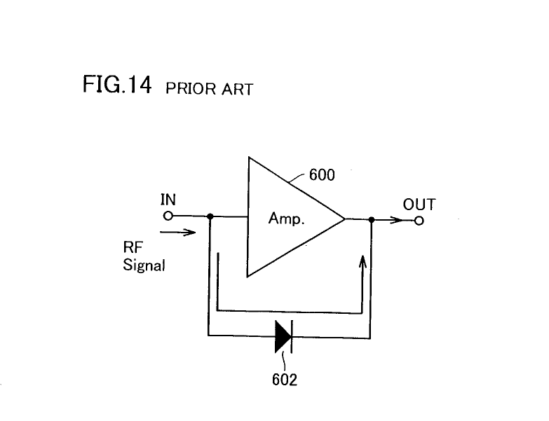

### DESCRIPTION OF THE PREFERRED EMBODIMENTS

Embodiments of the present invention will be described in detail hereinafter with reference to the drawings. The same reference numeral denotes the same or corresponding parts.

First Embodiment

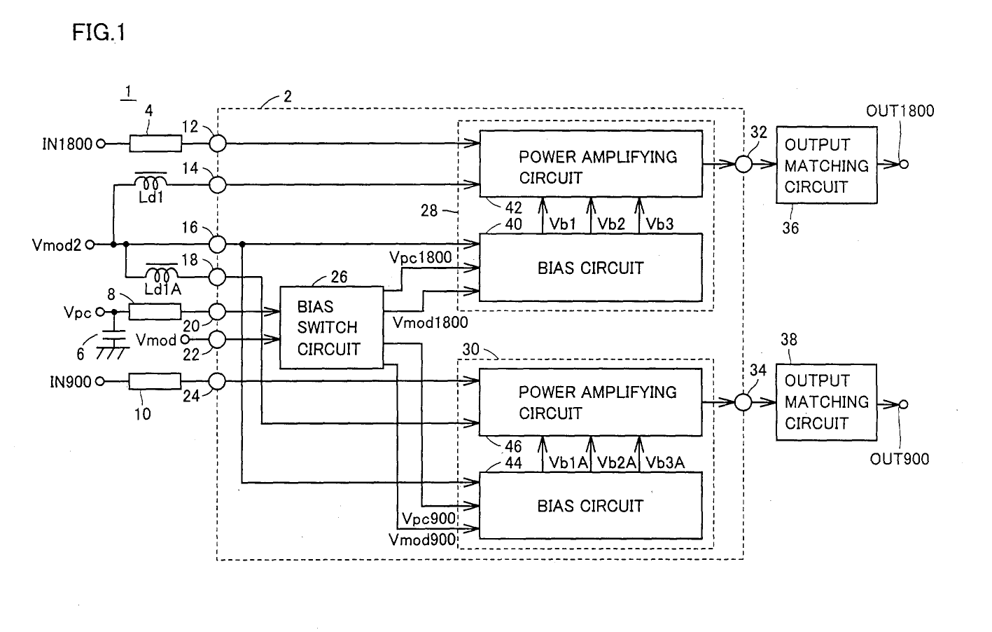

FIG. 1 is a schematic block diagram showing the configuration of a power amplifier 1 of a first embodiment of the present invention.

Referring to FIG. 1, a power amplifier 1 includes a semiconductor device 2 integrated on a compound semiconductor substrate made of gallium arsenide or the like, lines 4, 8 and 10, inductances Ld1 and Ld1A for blocking RF signals, a capacitor 6, and output matching circuits 36 and 38.

Semiconductor device 2 includes input terminals 12 to 24 and output terminals 32 and 34.

To input terminal 12, an input signal IN1800 in the 1800 MHz band is supplied via line 4. To input terminal 14, a mode select voltage Vmod2 is applied via inductance Ld1. To input terminal 18, mode select voltage Vmod2 is applied via inductance Ld1A. Input terminal 16 is directly connected to a terminal receiving mode select voltage Vmod2. To input terminal 20, a control voltage Vpc is applied via line 8.

Capacitor 6 is connected between one end to which control voltage Vpc is applied of line 8 and the ground node. To input terminal 22, band select voltage Vmod for making a switch between the 1800 MHz band and the 900 MHz band is applied. An input signal IN900 in the 900 MHz band is applied to input terminal 24 via line 10.

Semiconductor device 2 further includes: a bias switch circuit 26 for receiving control voltage Vpc and band select voltage Vmod from input terminals 20 and 22, respectively, and outputting a control voltage Vpc1800, Vmod1800, Vpc900 and Vmod900; an amplification part 28 activated according to control voltages Vpc1800 and Vmod1800, for amplifying signal IN1800 in the 1800 MHz band in an operation mode according to mode select voltage Vmod2; and an amplification part 30 activated according to control voltages Vpc900 and Vmod900, for amplifying signal IN900 in the 900 MHz band in a mode according to mode select voltage Vmod2.

Bias switch circuit 26 generates internal control voltages as shown in the following Table 1 in accordance with control voltage Vpc and the band select voltage. For convenience of description, mode select voltage Vmod2 for switching the mode is also written in Table 1.

TABLE 1

| | Input | | | | | | |
|---|---|---|---|---|---|---|---|
| Mode | | | Vmod- | Internal Control Voltage | | | |
| Frequency | Vpc | Vmod | 2 | Vpc900 | Vpc1800 | Vmod900 | Vmod1800 |
| OFF | 0 V | — | 0 V | 0 V | 0V | — | — |
| GSM | VpC | L | 0 V | Vpc | L | L | H |
| 900 MHz | | | | (Active) | (Inactive) | (Active) | (Inactive) |
| GSM | Vpc | H | 0 V | L | Vpc | H | L |
| 1800 MHz | | | | (Inactive) | (Active) | (Inactive) | (Active) |
| EDGE | Vpc | L | H | Vpc | L | L | H |
| 900 MHz | | | | (Active) | (Inactive) | (Active) | (Inactive) |
| EDGE | Vpc | H | H | L | Vpc | H | L |
| 1800 MHz | | | | (Inactive) | (Active) | (Inactive) | (Active) |

Referring to Table 1, when control voltage Vpc is set to 0V, amplification parts 28 and 30 are turned off.

When control voltage Vpc is in an active state, control voltage Vpc is transmitted to one of amplification parts 28 and 30 designated by band select voltage Vmod. When band select voltage Vmod is at the L level, amplification part 30 for the 900 MHz band is selected, and bias switch circuit 26 outputs control voltage Vpc as internal control voltage Vpc900. Internal control voltage Vpc1800 is set to the L level indicative of an inactive state.

On the other hand, when band select voltage Vmod is at the H level, amplification part 28 for the 1800 MHz band is selected, and bias switch circuit 26 outputs control voltage Vpc as internal control voltage Vpc1800. Internal control voltage Vpc900 is set to the L level indicative of an inactive state.

Bias switch circuit 26 also outputs internal control voltages Vmod900 and Vmod1800 in accordance with band select voltage Vmod. When band select voltage Vmod is at the H level, bias switch circuit 26 activates internal control voltage Vmod1800 to the L level and inactivates internal control voltage Vmod900 to the H level.

On the other hand, when band select voltage Vmod is at the L level, bias switch circuit 26 activates internal control voltage Vmod900 to the L level and inactivates internal control voltage Vmod1800 to the H level.

Internal control voltages Vpc900, Vpc1800, Vmod900 and Vmod1800 are determined as described above, and one of amplification parts 28 and 30 is selected. When mode select voltage Vmod2 is set to the L level, the selected amplification part operates in the GSM mode. When mode select voltage Vmod2 is set to the H level, the selected amplification part operates in the EDGE mode.

Amplification part 28 includes a bias circuit 40 for outputting bias voltages Vb1, Vb2 and Vb3 in accordance with mode select voltage Vmod2 and control voltages Vpc1800 and Vmod1800, and a power amplifying circuit 42 for receiving bias voltages Vb1, Vb2 and Vb3, amplifying signal IN1800 by the gain according to mode select voltage Vmod2, and outputting the resultant to terminal 32.

Amplification part 30 includes a bias circuit 44 for outputting bias voltages Vb1A, Vb2A and Vb3A in accordance with mode select voltage Vmod2 and control voltages Vpc900 and Vmod900, and a power amplifying circuit 46 for receiving bias voltages Vb1A, Vb2A and Vb3A, amplifying signal IN900 by the gain according to mode select voltage Vmod2, and outputting the resultant to terminal 34.

A signal is outputted from terminal 32 to output matching circuit 36 and passes through output matching circuit 36, and a signal OUT1800 is outputted from the output terminal. A signal is outputted from terminal 34 to output matching circuit 38 and passes through output matching circuit 38, and an output signal OUT900 is outputted from the output terminal.

Although a path for supplying a power supply potential to amplification parts 28 and 30 is not described in FIG. 1, more detailed description including the power supply path will be made hereinafter. In FIG. 1, since the band of a signal to be processed in amplification part 30 and that of amplification part 28 are different from each other, parameters of a transistor, a resistor, and a capacitor on the inside are different from each other. However, the circuit configurations are similar to each other. Consequently, the configuration of amplification part 28 will be representatively described.

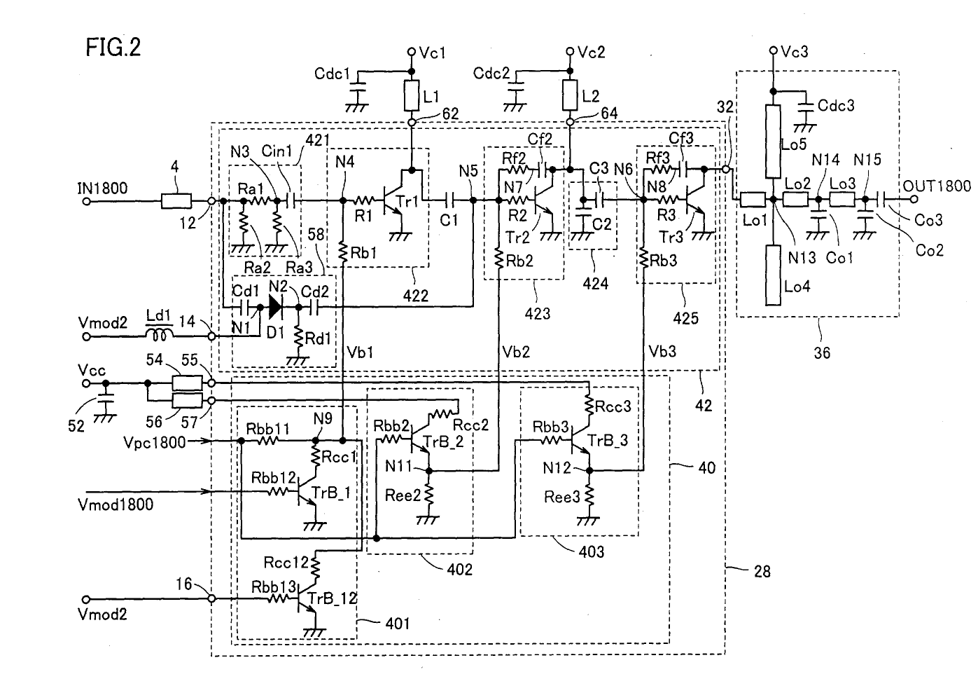

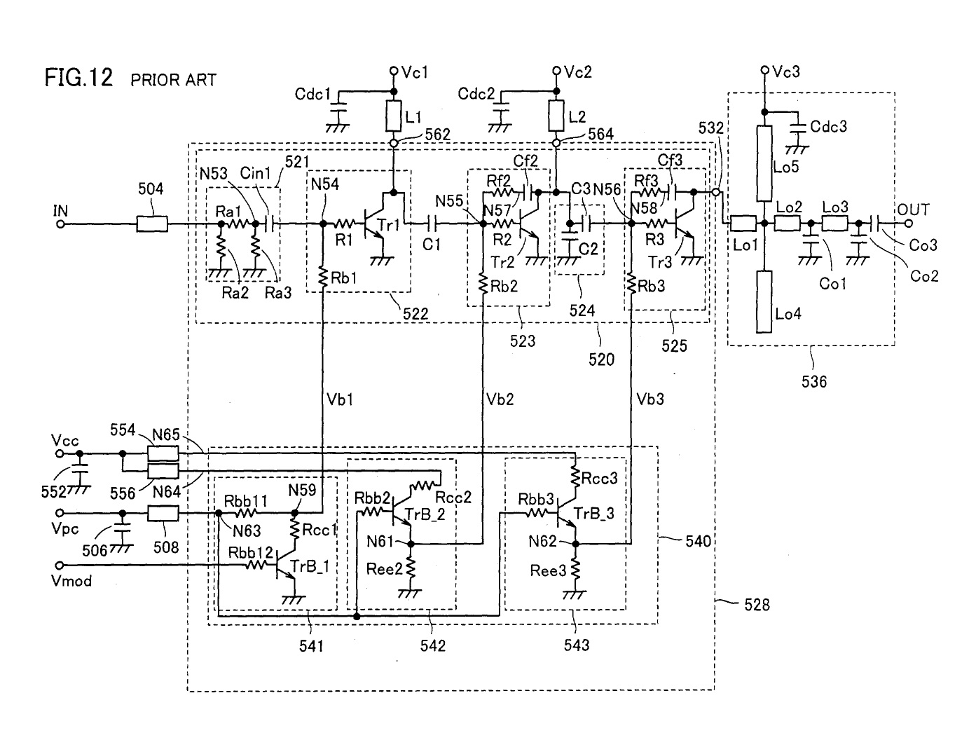

FIG. 2 is a circuit diagram showing the configuration of amplification part 28 in FIG. 1. The same reference numerals are designated to circuit elements such as resistors, transistors, and capacitors as those in the conventional circuit of FIG. 12.

Referring to FIG. 2, in addition to the input signals described in FIG. 1, the power supply potential is applied to amplification part 28 via terminals 55, 57, 62 and 64 provided for semiconductor device 2. Power supply potential Vcc is applied to terminal 55 via a line 54 for power supply. Power supply potential Vcc is applied to terminal 57 via a line 56 for power supply. A capacitor 52 is provided between a terminal commonly connected to lines 54 and 56 and to which power supply potential Vcc is applied and the ground node.

Collector power supply potential Vc1 is supplied to terminal 62 via line L1 for power supply. Capacitor Cdc1 is connected between one end to which collector power supply potential Vc1 is supplied of line L1 and the ground node. Collector power supply potential Vc2 is applied to terminal 64 via line L2 for power supply. Capacitor Cdc2 is connected between one end to which collector power supply potential Vc2 is supplied of line L1 and the ground node.

Bias circuit 40 includes bias voltage control circuits 401, 402 and 403 for outputting bias voltages Vb1, Vb2 and Vb3, respectively.

Bias voltage control circuit 401 includes: a resistor Rbb1 having an end to which control voltage Vpc1800 is applied and the other end connected to a node N9; a resistor Rbb12 having one end to which control voltage Vmod1800 is applied; transistor TrB_1 having a base connected to the other end of resistor Rbb12 and an emitter connected to the ground node; and resistor Rcc1 connected between the collector of transistor TrB_1 and node N9. Bias voltage Vb1 is outputted from node N9.

Bias voltage control circuit 402 includes: resistor Rbb2 having an end to which control voltage Vpc1800 is applied; transistor TrB_2 having a base connected to the other end of resistor Rbb2 and an emitter connected to a node N11; resistor Ree2 connected between node N11 and the ground node; and resistor Rcc2 connected between terminal 57 and the collector of transistor TrB_2. Power supply potential Vcc is applied to terminal 57 via line 56. Capacitor 52 is connected between the terminal receiving power supply potential Vcc and the ground node. Bias voltage Vb2 is output from node N11.

Bias voltage control circuit 403 includes: resistor Rbb3 having an end to which control voltage Vpc1800 is applied; transistor TrB_3 having a base connected to the other end of resistor Rbb3 and an emitter connected to a node N12; resistor Ree3 connected between node N12 and the ground node; and resistor Rcc3 connected between terminal 55 and the collector of transistor TrB_3. Power supply potential Vcc is applied to terminal 55 via line 54. Bias voltage Vb3 is outputted from node N12.

Power amplifying circuit 42 includes: an input matching circuit 421 to which input signal IN1800 is supplied from an input terminal via line 4 and terminal 12; a first amplifier stage 422 for receiving and amplifying an output of input matching circuit 421; a second amplifier stage 423; a third amplifier stage 425; capacitor C1 for matching amplifier stages 422 and 423; and an interstage matching circuit 424 for matching amplifier stages 423 and 425.

Input matching circuit 421 includes resistors Ra1, Ra2 and Ra3 constructing an attenuator for receiving input signal IN1800 supplied via line 4, and capacitor Cin1 connected between nodes N3 and N4.

Amplifier stage 422 includes a resistor Rb1 having an end to which bias voltage Vb1 is applied and another end connected to node N4, resistor R1 having an end connected to node N4, and transistor Tr1 having a base connected to the other end of resistor R1 and an emitter connected to a ground node. The collector of transistor Tr1 is connected to terminal 62. Collector power supply potential Vc1 is applied to terminal 62 via line L1. Capacitor Cdc1 is provided between a terminal to which collector power supply potential Vc1 is applied and the ground node.

Capacitor C1 for matching amplifier stages 422 and 423 is connected between the collector of transistor Tr1 and a node N5.

Amplifier stage 423 includes: resistor Rb2 having an end to which bias voltage Vb2 is applied and the other end connected to node N5; resistor R2 having an end connected to node N5; transistor Tr2 having a base connected to the other end of resistor R2 and an emitter connected to the ground node; capacitor Cf2 connected between the collector of transistor Tr2 and a node N7; and resistor Rf2 connected between nodes N7 and N5. An output of transistor Tr2 is fed back to node N5 via capacitor Cf2 and resistor Rf2. The collector of transistor Tr2 is connected to terminal 64. Collector power supply potential Vc2 is applied to terminal 64 via line L2. Capacitor Cdc2 is connected between the terminal to which collector power supply potential Vc2 is applied and the ground node.

Amplifier stage 425 includes: resistor Rb3 having an end to which bias voltage Vb3 is applied and the other end connected to a node N6; resistor R3 having an end connected to node N6; transistor Tr3 having a base connected to the other end of resistor R3 and an emitter connected to the ground node; capacitor Cf3 connected between the collector of transistor Tr3 and a node N8; and resistor Rf3 connected between nodes N8 and N6. An output of transistor Tr3 is fed back to node N6 via capacitor Cf3 and resistor Rf3. The collector of transistor Tr3 is connected to terminal 32.

Output matching circuit 36 is connected to terminal 32. Collector power supply potential Vc3 is applied to output matching circuit 36, and signal OUT1800 is outputted from an output terminal.

Output matching circuit 36 includes: a line Lo1 connected between terminal 32 and node N13; a short stub Lo5 connected between a node to which collector power supply potential Vc3 is applied and node N13; a capacitor Cdc3 having an end connected to collector power supply potential Vc3 and the other end connected to the ground node; a line Lo2 connected between node N13 and a node N14; a capacitor Co1 connected between node N14 and the ground node; a line Lo3 connected between node N14 and a node N15; a capacitor Co2 connected between node N15 and the ground node; a capacitor Co3 connected between node N15 and an output terminal for outputting output signal OUT1800; and an open stub Lo4 having an end connected to node N13 and the other end as an open end.

Power amplifying circuit 42 further includes a signal transmission part 58 connected between terminal 12 and node N5, for transmitting signals in accordance with mode select voltage Vmod2. The point that power amplifying circuit 42 includes signal transmission part 58 is largely different from the conventional configuration described by referring to FIG. 12.

Signal transmission part 58 includes: capacitor Cd1 connected between terminal 12 and node N1; diode D1 connected between nodes N1 and N2; resistor Rd1 connected between node N2 and the ground node; and capacitor Cd2 connected between nodes N2 and N5. Mode select voltage Vmod2 is applied to node N1 via terminal 14 and inductance Ld1 for blocking RF signal. The direction from node N1 to node N2 is the forward direction of diode D1.

Switching of the gain of amplification part 28 according to mode select voltage Vmod2 will now be described.

The gain is switched by switching mode select voltage Vmod2 between the H level (for example, about 2.8V) and the L level (for example, about 0V). When mode select voltage Vmod2 is set to the H level, transistor TrB_1 is made conductive, node N9 is connected to the ground potential, and bias voltage Vb1 becomes about 0V. Consequently, transistor Tr1 included in the first amplifier stage 422 is turned off. On the other hand, in signal transmission part 58, the potential of node N1 is set to the H level.

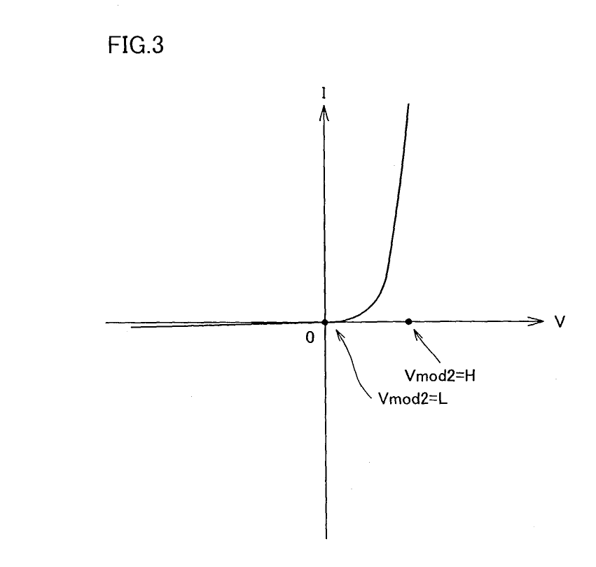

FIG. 3 is a diagram showing the characteristics of diode D1 of signal transmission part 58 in FIG. 2.

Referring to FIGS. 2 and 3, the cathode of diode D1 is connected to the ground node via resistor Rd1. Therefore, when the potential of node N1 is around 0V, a current does not flow through diode D1. In this case, even when input signal IN1800 is transmitted to node N1 via capacitor Cd1, the amplitude of the signal does not exceed an ON-state voltage in the forward direction of diode D1, so that no signal is transmitted to node N2.

On the other hand, when mode select voltage Vmod2 is at the H level, node N1 exceeds the ON-state voltage of diode D1 with respect to node N2, so that nodes N1 and N2 are made conductive. Therefore, when input signal IN1800 is transmitted via capacitor Cd1, the signal passes through diode D1 and is transmitted to node N2, and is further transmitted to node N5 via capacitor Cd2.

As described above, when mode select voltage Vmod2 is at the H level, input signal IN1800 is transmitted directly to the second amplifier stage 423 via signal transmission part 58. The signal is subjected to the amplifying process in each of two amplifier stages 423 and 425, and the resultant is outputted as output signal OUT1800.

In the case of setting mode select voltage Vmod2 to the H level to turn on diode D1, transistor TrB_12 is also turned on, bias voltage Vb1 becomes 0V, and power consumption in transistor Tr1 in a low gain operation is reduced. Thus, lower power consumption is achieved.

On the other hand, when mode select voltage Vmod2 is at the L level, as described above by referring to FIG. 3, diode D1 is in the off state. Therefore, an influence is hardly exerted on the normal amplifying operation. In this case, in bias voltage control circuit 401, bias voltage Vb1 is set to a proper potential in accordance with control voltage Vpc1800, so that signal IN1800 is amplified at amplifier stage 422. In this case, therefore, signal IN1800 is subjected to amplification at three amplifier stages 422, 423, and 425 and the resultant is outputted as signal OUT1800.

As described above, according to the first embodiment, the power amplifier of the gain switch type with the GSM/EDGE mode switching function can be provided without increasing noise power in the reception band.

Diode D1 is usually realized by using a PN junction. Alternately, a transistor can be used as a diode.

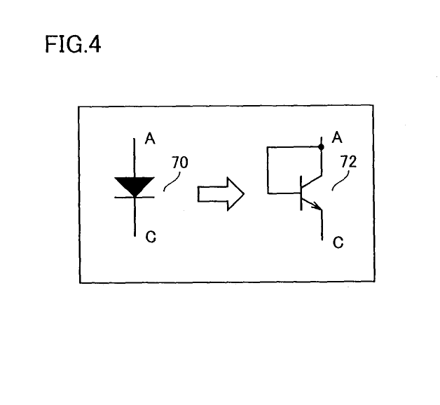

FIG. 4 is a diagram for describing the case where a transistor is used as diode D1.

Referring to FIG. 4, to use a transistor 72 in place of a diode 70, it is sufficient to connect the collector and base of transistor 72 to each other so that the resultant is used as an anode, and to use the emitter as a cathode. In such a manner, diode D1 can be realized by using a transistor.

Second Embodiment

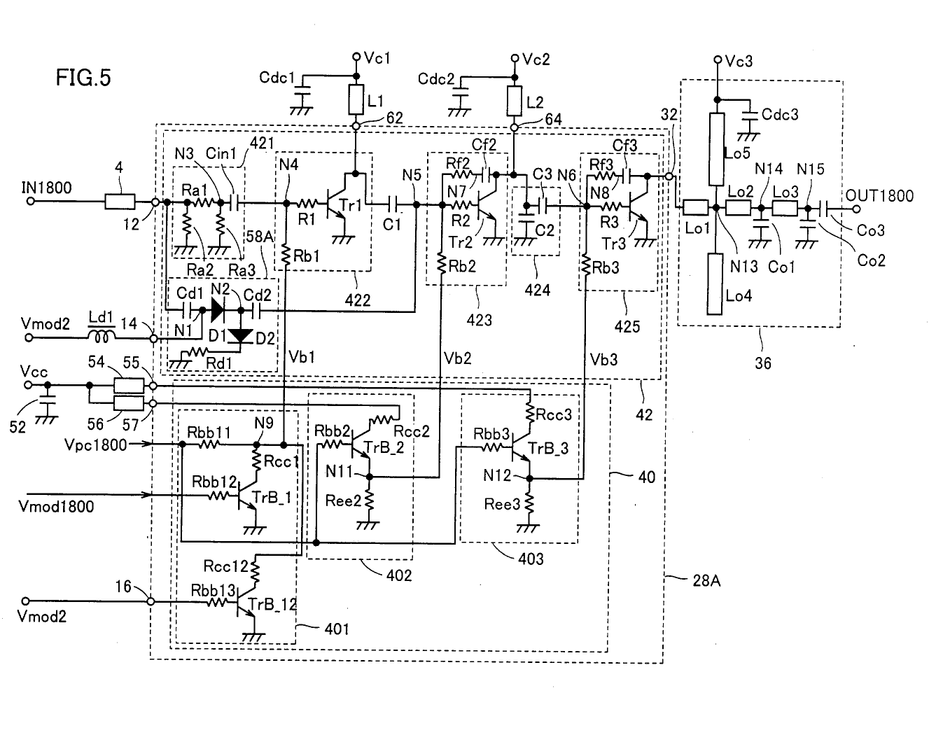

FIG. 5 is a circuit diagram showing the configuration of an amplification part 28A used in place of amplification part 28 in a power amplifier of a second embodiment.

Referring to FIG. 5, amplification part 28A includes a signal transmission part 58A in place of signal transmission part 58 in the configuration of amplifier 28 shown in FIG. 2.

Signal transmission part 58A includes capacitor Cd1 connected between terminal 12 and node N1, diode D1 connected between nodes N1 and N2, and capacitor Cd2 connected between nodes N2 and N5.

Signal transmission part 58A further includes a diode D2 having an anode connected to node N2, and resistor Rd1 connected between the cathode of diode D2 and the ground node. Diode D2 is connected so that its forward direction is the direction from node N2 to resistor Rd1.

By adding diode D2, a signal leakage from node N5 to resistor Rd1 is suppressed in the case where transistor Tr1 is in the on state and diode D1 is in the off state for the reason that, in the case where mode select voltage Vmod2 is at the L level at which transistor Tr1 is in the on state, not only diode D1 but also diode D2 are in the off state. Therefore, transmission of an RF signal to transistor Tr2 in a normal operation is performed more efficiently as compared with the case of the first embodiment.

As described above, in the second embodiment as well, without increasing noise power in the reception band, the gain switch type power amplifier with a GSM/EDGE mode switching function can be provided.

Third Embodiment

In the first and second embodiments, diode D1 is turned on and signal transmission parts 58 and 58A transmit input signal IN1800 to node N5. However, the input signal transmitted to node N5 is transmitted not only to transistor Tr2 but also to transistor Tr1 via capacitor C1. Since the signal is distributed in such a manner, a problem of interstage mismatch such that an RF signal cannot be inputted to transistor Tr2 efficiently even if transistor Tr1 is in the off state is predicted.

Further, in the case of the first embodiment, even in the case where diode D1 in FIG. 2 is in the off state and transistor Tr1 is in the on state, an output of transistor Tr1 includes a component transmitted from node N5 to transistor Tr2 side and a component leaked to resistor Rd1. In this case as well, a problem such that signal transmission is not efficiently performed is predicted.

In the third and subsequent embodiments, a power amplifier capable of solving such problems will be described.

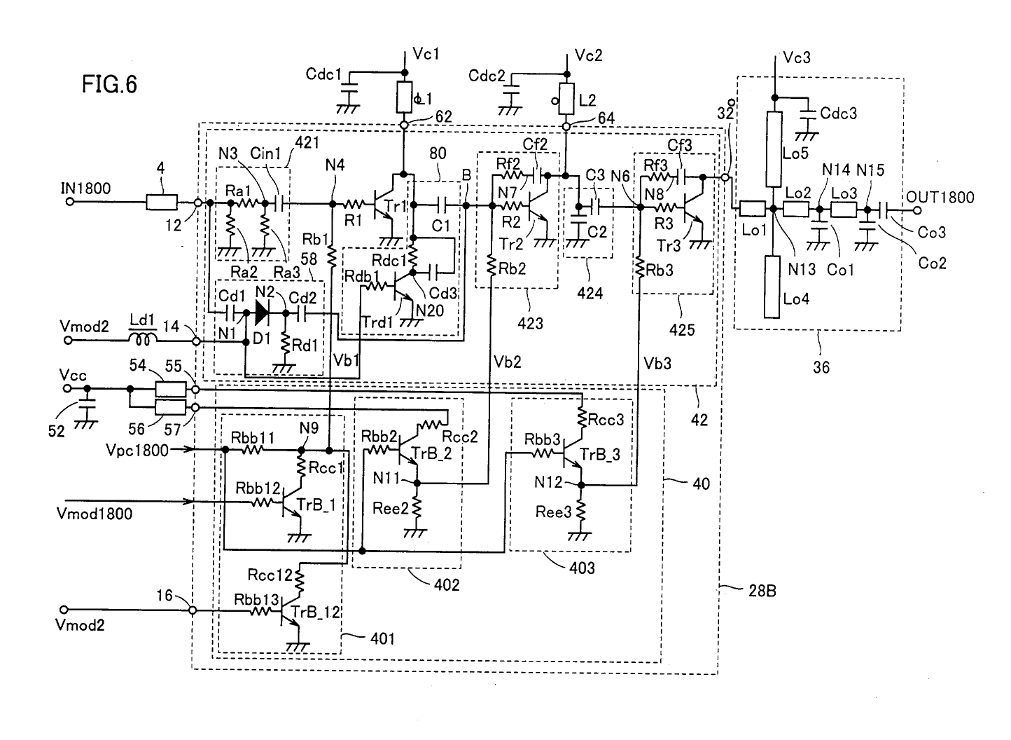

FIG. 6 is a circuit diagram showing the configuration of an amplification part 28B used in place of amplification part 28 shown in FIG. 2, in the third embodiment.

Referring to FIG. 6, amplification part 28B includes an interstage matching circuit 80 in place of capacitor C1 in the configuration of amplification part 28 shown in FIG. 2. Interstage matching circuit 80 includes: capacitor C1 connected between terminal 62 to which the collector of transistor Tr1 is connected and node N5; resistor Rdc1 and capacitor Cd3 connected in parallel between terminal 62 and a node N20; transistor Trd1 having a collector connected to node N20 and an emitter connected to the ground node; and resistor Rdb1 connected between the base of transistor Trd1 and terminal 14.

Since the configuration of the other part of amplification part 28B is similar to that of amplification part 28 described in FIG. 2, its description will not be repeated.

A switching operation will now be described. First, in the case where mode select voltage Vmod2 is 0V, diode D1 and transistor Trd1 are in the off state. Therefore, signal transmission part 58, resistor Rdc1, and capacitor Cd3 hardly exert an, influence on the amplifying operation of transistor Tr1.

On the other hand, when mode select voltage Vmod2 is at the H level, diode D1 is in the on state, and transistor Trd1 is made conductive by using resistor Rdc1 as a load. A sufficiently large value as compared with the impedance of capacitor Cd3 is selected for load resistor Rdc1. By using a sufficiently large resistance value for resistor Rdb1, signal leakage from the anode of diode D1 can be sufficiently reduced.

At this time, transistor Tr1 is in the off state due to conduction of transistor TrB_1. The capacitance value of capacitor Cd3 is selected so as to produce parallel resonance with the parasitic capacitance in the case where the inductance of line L1 connected to terminal 62 and transistor Tr1 are off. It makes the impedance in the direction of seeing transistor Tr1 side from node N5 becomes sufficiently high at a desired frequency. Therefore, signal leakage from node N5 to transistor Tr1 side is suppressed. As a result, an RF signal transmitted to node N5 via signal transmission part 58 is efficiently transmitted to transistor Tr2.

In the third embodiment as well, a gain switch type power amplifier capable of switching the GSM/EDGE modes without increasing noise power in the reception band can be provided. Further, in the EDGE mode in which the gain is decreased, signal transmission efficiency can be improved.

Fourth Embodiment

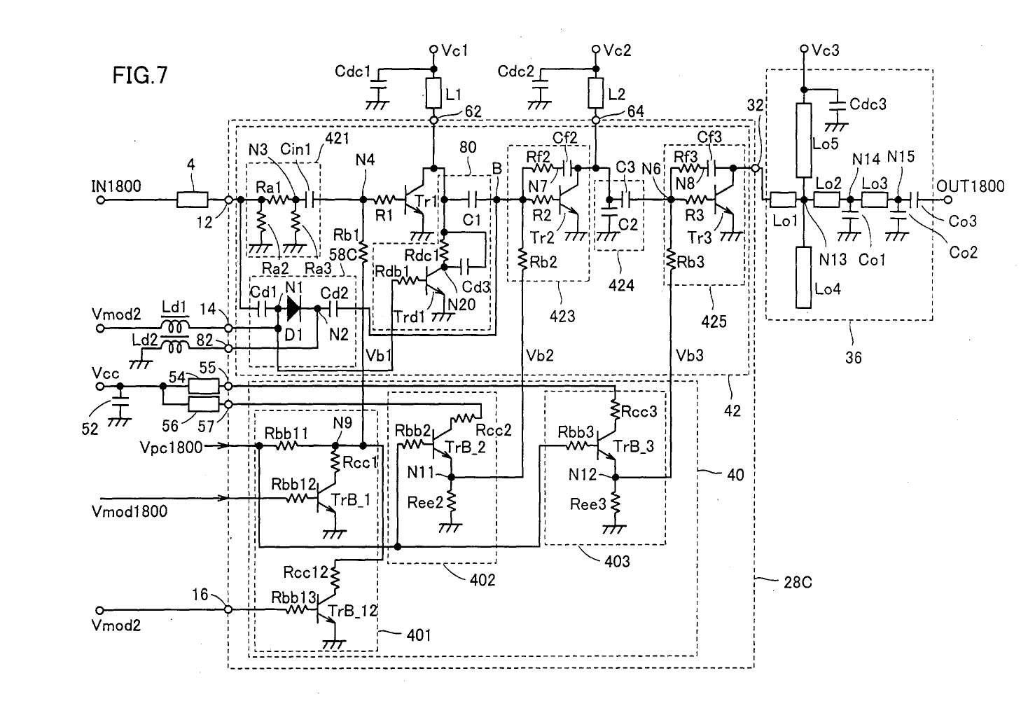

FIG. 7 is a circuit diagram showing the configuration of an amplification part 28C used in a power amplifier of a fourth embodiment.

Referring to FIG. 7, amplification part 28C includes a signal transmission part 58C in place of signal transmission part 58 in the configuration of amplification part 28B shown in FIG. 6.

Signal transmission part 58C includes capacitor Cd1 connected between terminal 12 and node N1, diode D1 connected between nodes N1 and N2, and capacitor Cd2 connected between nodes N2 and N5. Node N2 of signal transmission part 58C is connected to a terminal 82. Between terminal 82 and the ground node, an inductance Ld2 for blocking RF signal is connected.

By replacing resistor Rd1 in FIG. 6 with inductance Ld2, signal leakage from node N5 to resistor Rd1 in the case where transistor Tr1 is on and diode D1 is off can be suppressed. Therefore, transmission of an RF signal to transistor Tr2 in the GSM mode is efficiently performed.

In the EDGE mode where diode D1 is in the on state, signal leakage from node N5 to transistor Tr1 side is suppressed by interstage matching circuit 80. As a result, an RF signal is efficiently transmitted to transistor Tr2 also in the EDGE mode.

Also in the case of the fourth embodiment, a gain switch type power amplifier capable of switching the GSM/EDGE modes without increasing noise power in the reception band can be provided. In the EDGE mode, in the case of FIG. 5, two diodes D1 and D2 have to be turned on but, in the case of FIG. 7, it is sufficient to turn on only one diode D1. Therefore, this case has an advantage that the H level of mode select voltage Vmod2 can be made lower than that in the circuit of FIG. 5.

On the other hand, since inductance Ld2 for blocking RF signal has to be connected on the outside of the semiconductor device, this case has a disadvantage such that the mounting area is increased.

Fifth Embodiment

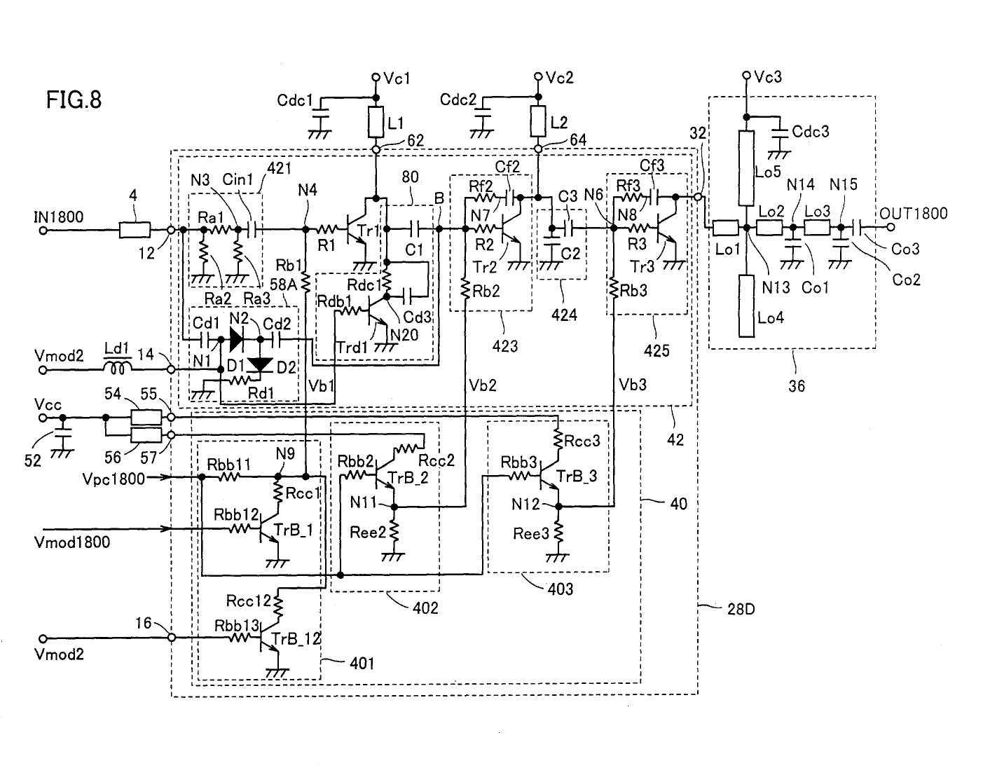

FIG. 8 is a circuit diagram showing the configuration of an amplification part 28D used in a fifth embodiment.

Referring to FIG. 8, amplification part 28D includes signal transmission part 58A in place of signal transmission part 58 in the configuration of amplification part 28B shown in FIG. 6. As the configuration of signal transmission part 58A has been described by referring to FIG. 5, its description will not be repeated.

Since the configuration of the other part of amplification part 28D is similar to that of amplification part 28B shown in FIG. 6, its description will not be repeated.

In the fifth embodiment as well, a gain switch type power amplifier capable of switching the mode between the GSM/EDGE modes without increasing a noise current in the reception band can be provided.

Further, by applying a load of diode D2 to resistor Rd1 in series, signal leakage from node N5 to resistor Rd1 in the case where transistor Tr1 is on and diode D1 is off is suppressed since diode D2 is turned off. Therefore, an RF signal is efficiently transmitted to transistor Tr2 in the GSM mode.

On the other hand, since the capacitance value of capacitor Cd3 is selected so as to produce parallel resonance in a manner similar to the fourth embodiment, signal leakage from node N5 to transistor Tr1 side in the state where diode D1 is on is suppressed. As a result, an RF signal is efficiently transmitted to transistor Tr2 in the EDGE mode.

In the fifth embodiment as well, it is unnecessary to provide inductance Ld2 for blocking an RF signal in the fourth embodiment, there is an advantage that the circuit scale can be reduced. On the other hand, the method has a disadvantage such that the potential of the H level of mode select voltage Vmod2 has to be increased by an amount to turn on both diodes D1 and D2.

Sixth Embodiment

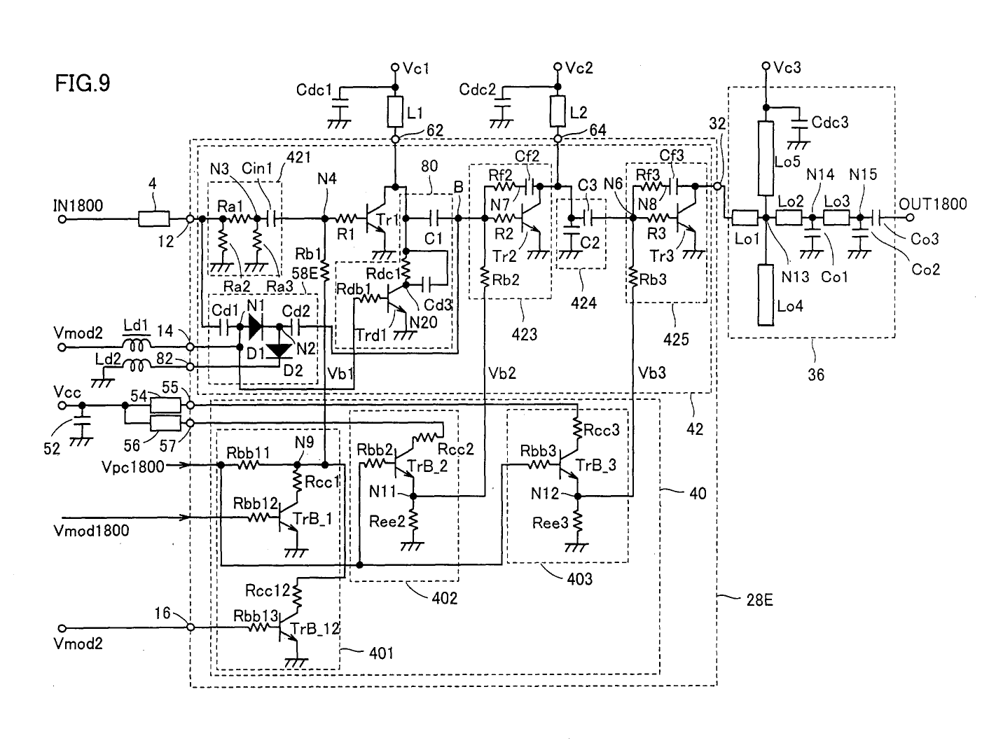

FIG. 9 is a circuit diagram showing the configuration of an amplification part 28E used in the sixth embodiment.

Referring to FIG. 9, amplification part 28E includes a signal transmission part 58E in place of signal transmission part 58C in the configuration of amplification part 28C described by referring to FIG. 7.

Signal transmission part 58E includes capacitor Cd1 connected between terminal 12 and node N1, diode D1 connected between nodes N1 and N2, capacitor Cd2 connected between nodes N2 and N5, and diode D2 connected between node N2 and a terminal 82. Between terminal 82 and the ground node, inductance Ld2 for blocking RF signal is connected. Signal transmission part 58E is different from signal transmission part 58C of FIG. 7 with respect to the point that diode D2 is added between node N2 and terminal 82.

Since the configuration of amplification part 28E is similar to that of amplification part 28C in FIG. 7, its description will not be repeated.

In the sixth embodiment as well, a gain switch type power amplifier capable of switching the mode between the GSM/EDGE modes without increasing noise power in the reception band can be provided.

By connecting diode D2 so that the direction from node N2 to node N8 is set to the forward direction, signal leakage from node N5 to inductance Ld2 in the GSM mode in which transistor Tr1 is on and diode D1 is off is suppressed.

On the other hand, in the EDGE mode in which diode D1 is on, signal leakage from node N5 to transistor Tr1 side is suppressed by interstage matching circuit 80. As a result, an RF signal is transmitted efficiently to transistor Tr2 also in the EDGE mode. Further, by properly setting the value of inductance Ld2 and the value of capacitor Cd2, inputs to transistor Tr2 in the state where diode D1 can be easily matched.

Seventh Embodiment

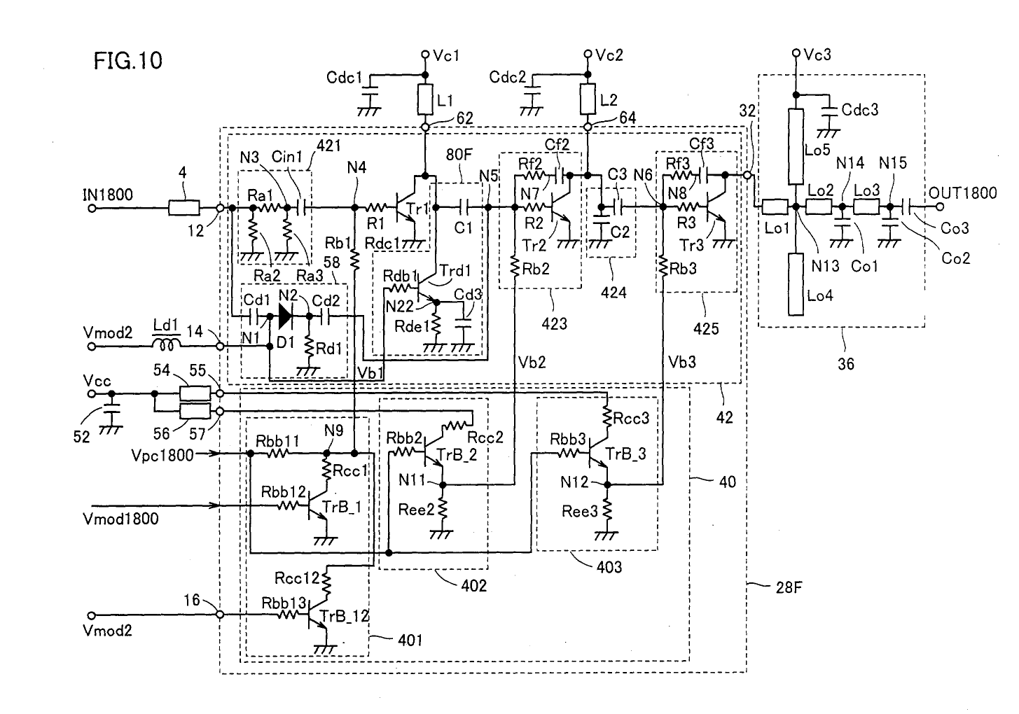

FIG. 10 is a circuit diagram showing the configuration of an amplification part 28F used in a seventh embodiment.

Referring to FIG. 10, amplification part 20F includes an interstage matching circuit 80F in place of interstage matching circuit 80 in the configuration of amplification part 28B described by referring to FIG. 6.

Interstage matching circuit 80F includes capacitor C1 connected between terminal 62 and node N5, transistor Trd1 having a collector connected to terminal 62 and an emitter connected to a node N22, resistor Rde1 connected between node N22 and the ground node, capacitor Cd3 connected between node N22 and the ground node, and resistor Rdb1 connected between node N1 and the base of transistor Trd1.

In interstage matching circuit 80F as well, the resistance value of resistor Rde1 and the capacitance value of capacitor Cd3 are selected so as to produce parallel resonance when transistor Tr1 is made conductive, thereby enabling signal leakage from node N5 to transistor Tr1 side to be suppressed in the EDGE mode where transistor Tr1 is in the off state.

Modification of Seventh Embodiment

In the configuration of amplification part 28F shown in FIG. 10, by providing signal transmission part 58C, terminal 82 and inductance Ld2 shown in FIG. 7 in place of signal transmission part 58, effects similar to those of the fourth embodiment can be obtained.

By providing signal transmission part 58A in FIG. 8 in place of signal transmission part 58 in the configuration of amplification part 28F shown in FIG. 10, effects similar to those of the fifth embodiment can be obtained.

In the configuration of amplification part 28F shown in FIG. 10, by providing signal transmission part 58E, terminal 82 and inductance Ld2 in FIG. 9 in place of signal transmission part 58, effects similar to those in the sixth embodiment can be obtained.

Eighth Embodiment

In an eighth embodiment, diode D1 of the transmission part in each of the first to seventh embodiments is replaced with a switch circuit 100G.

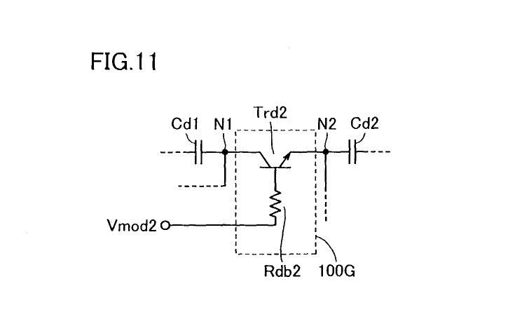

FIG. 11 is a circuit diagram showing the configuration of switch circuit 100G.

Referring to FIG. 11, switch circuit 100G includes transistor Trd2 having a collector connected to node N12 and an emitter connected to node N2, and resistor Rdb2 having an end to which mode select voltage Vmod2 is applied and the other end connected to the base of transistor Trd2.

When mode select voltage Vmod2 is set to the H level, switch circuit 100G connects nodes N1 and N2. Since node N2 is connected to the ground node via a resistor and an inductance, a voltage exceeding Vbe is applied across the base and emitter of transistor Trd2.

Also by using switch circuit 100G, effects similar to those in the first to seventh embodiments are obtained. In the case where the amplitude of an input signal is large, the diode is made conductive whereas a transistor can interrupt an input signal irrespective of the amplitude of the input signal.

In the eighth embodiment as well, a gain switch type power amplifier capable of switching the mode between the GSM/EDGE modes without increasing noise power in the reception band can be provided.

As described above, by providing a transmission circuit in parallel with the first amplification stage including a transistor, the gain can be switched without increasing noise power in the reception band. A loss at the time of signal transmission in the case of switching the gain of the power amplifier is reduced, and efficient signal transmission can be performed.

Since a transistor at the first stage is turned off when the gain is low, excessive current consumption can be reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A power amplifier having first and second modes as operation modes, comprising:
a first amplifying element which amplifies an input signal in said first mode and is set in an inactive state in said second mode;
a second amplifying element for further amplifying an output of said first amplifying element in said first mode and amplifying said input signal in said second mode; and
a transmission circuit performing a first operation of blocking transmission of said input signal to said second amplifying element in said first mode and a second operation of transmitting said input signal to said second amplifying element in said second mode, and switching said first and second operations in accordance with a mode setting signal.

2. The power amplifier according to claim 1, wherein
said transmission circuit includes
a first capacitor connected between a signal input node for receiving said input signal and a first internal node;
a switch circuit connected between said first internal node and a second internal node, which is controlled to be conductive or nonconductive with respect to said input signal in accordance with said mode setting signal; and
a second capacitor connected between said second internal node and an input of said second amplifying element.

3. The power amplifier according to claim 2, wherein
said switch circuit has a diode having an anode connected to said first internal node and a cathode connected to said second internal node, and
an input bias voltage which differs in said first and second modes in accordance with said mode setting signal is applied to the anode of said diode.

4. The power amplifier according to claim 2, wherein
said switch circuit has a transistor connected between said first internal node and said second internal node, having a control electrode receiving said mode setting signal.

5. The power amplifier according to claim 2, wherein
said transmission circuit further includes a resistor connected between said second internal node and a node to which a fixed bias voltage is applied.

6. The power amplifier according to claim 2, further comprising
an inductance connected between said second internal node and a node to which a fixed bias voltage is applied.

7. The power amplifier according to claim 2, wherein
said transmission circuit further includes
a diode having an anode connected to said second internal node; and
a resistor connected between a cathode of said diode and a node to which a fixed bias voltage is applied.

8. The power amplifier according to claim 2, wherein
said transmission circuit further includes
a diode having an anode connected to said second internal node; and the power amplifier further comprising
an inductance connected between a cathode of said diode and a node to which a fixed bias voltage is applied.

9. The power amplifier according to claim 1, further comprising
a matching circuit connected between an output of said first amplifying element and an input of said second amplifying element, in which a first impedance seen in the direction from the output of said first amplifying element to the input of said second amplifying element is set to a value so that an output signal of said first amplifying element can be transmitted to the input of said second amplifying element in said first mode, and a second impedance seen in the direction from the input of said second amplifying element to the output of said first amplifying element is set to a value so that transmission of said input signal from the input of said second amplifying element to the output of said first amplifying element can be blocked in said second mode.

10. The power amplifier according to claim 9, wherein
said matching circuit includes
a capacitor forming a parallel resonance circuit with respect to an inductive reactance and a capacitive reactance which are parasitic on the output of said first amplifying element in said second mode; and
a switch circuit for connecting said capacitor between the output of said first amplifying element and a fixed potential in said second mode, and setting at least one of electrodes of said capacitor to an open state in said first mode.

11. The power amplifier according to claim 10, wherein
one end of said capacitor is connected to the output of said first amplifying element, and
said switch circuit includes a transistor connected between the other end of said capacitor and a node to which said fixed potential is applied, which is switched between a conductive state and a nonconductive state in accordance with said mode setting signal.

12. The power amplifier according to claim 10, wherein
one end of said capacitor is connected to a node to which a fixed potential is applied, and
said switch circuit has a transistor connected between the other end of said capacitor and the output of said first amplifying element, which is switched between a conductive state and a nonconductive state in accordance with said mode setting signal.

13. The power amplifier according to claim 1, wherein
each of said first and second amplifying elements is a hetero-junction bipolar transistor.
